(19) United States
(12) Patent Application Publication
(10) Pub. No.: US 2026/0323863 A1
(43) Pub. Date: Oct. 15, 2026

(54) INTERFACE

(71) Applicants: WAIYS AS, Oslo (NO); Ørsted Wind Power A/S, Fredericia (DK)

(72) Inventor: Marie Andrea STENFELDT, Skånevik (NO)

(21) Appl. No.: 19/122,612

(22) PCT Filed: Oct. 19, 2023
(86) PCT No.: PCT/NO2023/060075

§ 371 Date: Apr. 18, 2025

(30) Foreign Application Priority Data
Oct. 21, 2022 (NO) 20221135

(51) Int. Cl. H05K 7/14; G06F 1/16; G06F 1/20; H05K 5/02

(52) U.S. Cl. CPC H05K 7/1497; G06F 1/1632; G06F 1/20; H05K 5/0204; H05K 5/0208; H05K 5/0286

(57) ABSTRACT

A system and method for interfacing a module for computation with local 5 infrastructure is provided. The object of the invention is achieved using a receptacle (300) for a module (400) for computation, wherein the receptacle (300) comprises a mating interface (350), and module interface (450) for a module (400) for computation, wherein two interfaces are matched.

### BACKGROUND OF THE INVENTION

### Field of the Invention

The invention relates to interfaces in general and more specifically a system and a method for interfacing a module for computation with local infrastructure.

### Background Art

State of the art is reflected in (closest prior art)

From prior art one should refer to installations of modules. Modules are installed and required connections for power, networking, control, cooling are attached to local infrastructure. Modules are often special purpose and there is a lot of work and adaptions for attachment to local infrastructure.

US 2017/0344060 A1, discloses according to the abstract, a docking station capable of docking and undocking a portable computing device.

US 2020/0060033 A1, discloses according to the abstract, a server node controller mounted in a chassis configured to be inserted into a server node slot of a server node grid. The chassis includes a blind-mate connector system on a back side that includes a blind-mate power connector and a blind-mate network connector configured to blind-mate with a corresponding blind-mate power connector and a corresponding blind-mate network connector of the server node slot of the server node grid. As the server node is inserted into the server node slot, the blind-mate power connector is configured to blind-mate with the corresponding blind-mate power connector of the server node slot before the blind-mate network connector blind-mates with the corresponding blind-mate network connector of the server node slot, such that the blind-mate power connector provides alignment guidance for the blind-mate network connector.

US 2010/0265652 A1, discloses according to the abstract, a docking device for portable computers. The docking device includes a casing, a connector affixed to the casing, and a support member arranged on the casing. The support member is capable of being moved up and down via an elastic member disposed therebetween.

There is therefore a need for a method and a system to overcome the above mentioned problems.

### SUMMARY OF THE INVENTION

### Problems to be Solved by the Invention

Therefore, a main objective of the present invention is to provide a system and a method for interfacing a module for computation with local infrastructure.

### Means for Solving the Problems

The objective is achieved according to the invention by a receptacle for a module for computation as defined in the preamble of claim 1, having the features of the characterising portion of claim 1, a module interface for a module for computation as defined in the preamble of claim 5, having the features of the characterising portion of claim 5, a module for computation as defined in the preamble of claim 9, having the features of the characterising portion of claim 9, and a method for installing a module for computation as defined in the preamble of claim 10, having the features of the characterising portion of claim 10.

A number of non-exhaustive embodiments, variants or alternatives of the invention are defined by the dependent claims.

The present invention attains the above-described objective by a set of interfaces, a mating interface provided on a receptacle and a corresponding module interface provided on a module, wherein the interfaces comprise connectors for infrastructure such as power and networking.

In one aspect of the invention, a receptacle for a module for computation is provided, wherein the receptacle comprises a mating interface for connection to a corresponding module interface, wherein the mating interface comprises connectors for power and networking, wherein the module for computation is a standard freight container. Thus, when a container provided with a module interface is placed in a receptacle, connections are then made.

In one embodiment, the interface further comprises connectors for cooling. While the container may not need cooling, there are other situations where cooling is needed.

Such cooling can be performed using means local to the container, such as heat exchangers or heat pumps, one can also use cooling from a cooling circuit that is part of the infrastructure. Local resources such as sea water can also be used for cooling.

In one embodiment, the receptable comprises a mechanical interface adapted for locking a module for computation in place. This simplifies logistics, so that the receptacle takes care of the locking, without placing extra burden on the infrastructure in this regard.

In one embodiment, the receptable comprises a guide for guiding a module for computation in place during installation. This simplifies operations, especially when modules are lowered into place using a crane, and can also help in avoiding the need for personnel near the receptacle when handling large and heavy objects such as modules.

In a second aspect of the invention, a module interface for a module for computation is provided, wherein the module interface comprises connectors for power and networking, wherein the connectors are adapted for connection to a corresponding receptacle having a mating interface, wherein the module for computation is a standard freight container.

In one embodiment, the module interface further comprises connectors for cooling.

In one embodiment, the module interface further comprises a member for engaging with a receptacle comprising a mechanical interface adapted for locking a module for computation in place.

In one embodiment, the module interface further comprises a module guide to interface with a receptacle comprising a guide for guiding a module for computation in place during installation.

In a third aspect of the invention, a module for computation is provided, comprising a module interface for engaging with a receptable having a mating interface, wherein the module for computation is a standard freight container.

In a fourth aspect of the invention, a method for installing a module for computation is provided, comprising a module interface provided with a module guide, into a receptable, the method comprises the steps:
1) lowering the module until the module guide interfaces with a guide for guiding the module for computation in place
2) lowering the module further into the receptacle until the module interface connectors for power and networking connects to the corresponding connectors for power and networking of the receptacle. The use of the guides ensures the module is properly aligned with the receptacle before lowering into position. This avoids the use of personnel near the receptacle.

In one embodiment, the method further comprises the step of engaging mechanical interface adapted for locking the module for computation in place of the receptacle to the mechanical interface. This ensures the module is safely locked into position. This can be a combination of mechanical locking, securing contacts are in position, or both.

### Effects of the Invention

The present invention comprises a technological advantage over known systems and methods by use of interfaces according to embodiments of the present invention, in that designers of local facilities and infrastructure and designers of modules for computation can make their designs separately and be assured that the modules will fit and attach correctly to local infrastructure.

These effects provide in turn several further advantageous effects:
it makes it possible to easily, rapidly and reliably attach and remove modules,
it makes it possible to position modules into place without operators on the platform,
It simplifies logistics since the use of standard freight containers are well known in transport and logistics and also adapted for deployment,
it makes it possible to make connections automatically without manual work for attachment or detachment.

### BRIEF DESCRIPTION OF THE DRAWINGS

The above and further features of the invention are set forth with particularity in the appended claims and together with advantages thereof will become clearer from consideration of the following detailed description of an exemplary embodiment of the invention given with reference to the accompanying drawings.

The invention will be further described below in connection with exemplary embodiments which are schematically shown in the drawings, wherein:

FIG. 1 shows an overview of an offshore system embodiment.

### DESCRIPTION OF THE REFERENCE SIGNS

The following reference numbers and signs refer to the drawings:

| | |
|---|---|
| 100 | The system with infrastructure and module |
| 200 | Infrastructure |
| 210 | Platform for receptacle |
| 212 | Platform cabling |
| 220 | Power systems |
| 222 | Substation |
| 224 | Power station |
| 226 | Power cabling |
| 300 | Receptacle |
| 310 | Mechanical interface for locking module in place |
| 320 | Guide for guiding a module for computation in place |
| 350 | Mating interface |
| 352 | Connectors for power and networking |
| 354 | Connector for cooling |
| 400 | Module |
| 410 | Member for engaging with mechanical interface |
| 420 | Module guide |
| 450 | Module interface |
| 452 | Connectors for power and networking |
| 454 | Connector for cooling |

### DETAILED DESCRIPTION OF THE INVENTION

Various aspects of the disclosure are described more fully hereinafter with reference to the accompanying drawings. This disclosure may, however, be embodied in many different forms and should not be construed as limited to any specific structure or function presented throughout this disclosure. Rather, these aspects are provided so that this disclosure will be thorough and complete, and will fully convey the scope of the disclosure to those skilled in the art. Based on the teachings herein one skilled in the art should appreciate that the scope of the disclosure is intended to cover any aspect of the disclosure disclosed herein, whether implemented independently of or combined with any other aspect of the disclosure. For example, an apparatus may be implemented or a method may be practiced using any number of the aspects set forth herein. In addition, the scope of the disclosure is intended to cover such an apparatus or method which is practiced using other structure, functionality, or structure and functionality in addition to or other than the various aspects of the disclosure set forth herein. It should be understood that any aspect of the disclosure disclosed herein may be embodied by one or more elements of a claim.

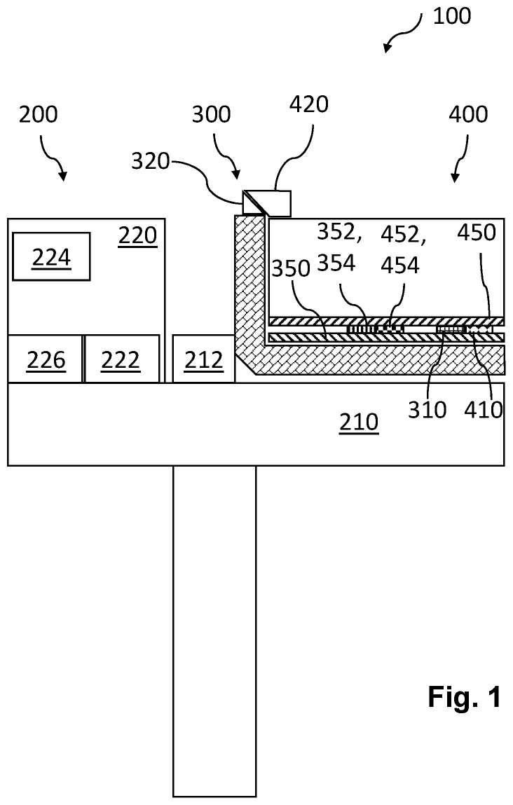

The invention will be further described in connection with exemplary embodiments which are schematically shown in the drawings, wherein FIG. 1 shows an overview of an offshore system embodiment, wherein the system 100 comprises some form of infrastructure 200 at a location. In this specific embodiment this is an offshore wind turbine location where the infrastructure comprises a platform 210 with associated cabling 212. The platform can be a platform attached to an offshore wind turbine generator (WTG) or a platform having a substation serving a field with a plurality of WTGs, or a platform attached to an offshore WTG co-located with a substation. The infrastructure 200 also comprises a power system 220 related to wind power, such as a substation 222 and/or a power station 224 in the form of a WTG. In alternative embodiments, the power station 224 is a gas turbine fed with surplus gas that otherwise would be flared off.

In some embodiments, the platform 210 is an oil and/or gas platform that optionally has been wholly or partly refurbished for alternative use.

According to prior art, modules are installed manually, and all connectors are connected using manual work using skilled workers such as welders, plumbers, electricians and engineers.

### Principles Forming the Basis of the Invention

In the present embodiment, a receptacle 300 is provided on the platform 210 and connected with the platform cabling 212. The receptacle is an interface part that is typically robust and smaller than the module 400. Often a module can be more fragile. One or more receptacles can be installed on the platform at the infrastructure owner's convenience, for instance during construction or refurbishing. During installation, it is not required to have any module in position, though one should make sure sufficient volume is allocated. A robust dummy module could be used to verify the construction and that a computing module can later be placed as intended.

The receptacle 300 typically comprises attachment means (not shown) for attachment to the platform. Several attachment points and means can be provided, for welding, gluing, bolting, concrete and other means, as would be well known in the art. The means for attachment to the platform can be separate from the attachment to the platform cabling 212, and will be up to the owner of the infrastructure.

The receptacle 300 comprises a mating interface 250 for connection to a corresponding module interface, wherein the mating interface comprises connectors 352 for power and networking. The mating interface may also comprise connectors 354 for cooling. The two interfaces are matched, like plug and socket, and operate similarly. While the receptacle is shown as a bed where the module rests and the interfaces are on an upper surface of the receptacle and underneath the module, this is nevertheless not the only embodiment. As an example, the module may be lowered into place and slid into position, wherein the receptacle and module interfaces are provided on a side surface.

The receptacle 300 comprises a mechanical interface 310 for locking a module in place. The locking module fixes the module in position, and can also be used to bring the module into a final position. In the example above with side surface interfaces, the locking module can be used to mate the module to the receptacle, and thus make the connection. In a preferred embodiment the locking module operates without the need of personnel near the receptacle, thus improving safety. The locking module can be operated electrically or hydraulically. The locking module may be located in the vicinity of the mating interface, in order to ensure minimum distance and thereby reduce mechanical distortions due to the forces used to lock the module into place.

The receptable 300 may comprise a guide 320 for guiding a module 400 for computation in place during installation. The guide preferably engages with a module guide 420. During installation, the module provided with a module interface 450 is lowered until it engages with the guide 320 in order to align the module to the receptacle as the module is brought into position. The guide can be fixed or detachably attached.

In the present embodiment, a module interface 450 is provided on module 400 for computation is provided. The module interface is the second interface, that matches the receptacle mating interface 350. The module interface is either attached to the module or part of the module. In the case where the module is a standard freight container, the module can be attached to the standard attachment points on freight containers. The container can be provided with doors (not shown) that when opened, expose the module interface. Alternatively the module interface can be fastened using traditional means such as welding, bolting etc.

The module interface 450 comprises connectors 452 for power and networking, wherein the connectors are adapted for connection to a corresponding receptacle 300 having a mating interface 350 with connectors 352 for power and networking.

In some embodiments, the module is cooled purely by convention. In some other embodiments, the module is provided with at least one heat pump, where a plurality of heat pumps provided redundancy and improved reliability. In yet other embodiments, cooling is obtained from the infrastructure 200. In this embodiment, the module interface further comprises connectors 454 for cooling.

The module interface 450 may further comprise a member 410 for engaging with a mechanical interface 310 adapted for locking a module 400 for computation in place.

The module interface 450 further comprises a module guide 420 to interface with a guide 320 for guiding a module for computation in place during installation. This module guide may have to withstand strong forces as the module guide slides against the guide 320 as the module is lowered into the receptacle. Wear may be expected, beneficially these module guides are detachably attached in case of excessive wear.

While the module guide 420 and the and the guide 320 are disclosed in scenarios relating to positioning a module 400 into a receptacle 300, these may also have utility when removing the module from the receptacle, in order to avoid damaging forces or movement during the process of lifting up the module 400.

In the present embodiment, a module 400 for computation is provided. Typically this module is a container having standard format, and is filled with computers and support equipment for computation. This comprises computers, networking equipment and cooling systems. In some embodiments cooling is performed using heat pumps such as air to air split air conditioners, maintaining a clean and controlled atmosphere inside the container.

In the present embodiment, a method for installing a module 400 provided with a module interface 450 is provided. Typically at least one receptacle 300 is prepositioned on a platform 210. A crane hook attached to the module, then the module raised up from an interim platform and then lowered until module guide 420 engages or interfaces with a guide 320 for guiding the module in place. Next the module is further lowered into the receptacle until the module is properly positioned and seated, and interface connectors for power and networking connects to the corresponding connectors for power and networking of the receptacle.

In offshore scenarios this may be done using a supply ship. Alternatively the offshore infrastructure is provided with a crane that lifts the container from a ship and into position.

It should be understood that by standard freight container it is meant any form of standardized container used in transport, such as but not limited to Intermodal or ISO containers, of any size, such as listed in ISO 668.

### BEST MODES OF CARRYING OUT THE INVENTION

The embodiment of the apparatus according to the invention shown in FIGS. 1 and 2 comprises.

In a preferred embodiment, the module is a standard freight container. While matching standard lengths for container and receptacle can be used, it is also possible for a receptacle to receive containers that are shorter then the receptacle, and with adaptions also receive containers longer than the receptacle, by having the receptacle open at one end, preferably the end distal from the mating interface.

### Alternative Embodiments

A number of variations on the above can be envisaged. For instance while the connectors may be electromechanical contacts that attach like plug into socket, it is also within the scope to use non-contact means of transferring power. Such means may be inductive power transfer systems.

Similarly, while networks may be attached like plug into socket, it is also within the scope to use non-contact means of networking. Such means may be RF technology such as WIFI, RFID or based on these, or be optical.

Non-contact systems can be beneficial in subsea applications, taking the advantage of convenient cooling.

### INDUSTRIAL APPLICABILITY

The invention according to the application finds use in deploying modules for computations, in an efficient manner.

1. A receptacle for a module for computation, wherein the receptacle comprises a mating interface for connection to a corresponding module interface, wherein the mating interface comprises connectors for power and networking,
wherein the module for computation is a standard freight container.

2. The receptable according to claim 1, wherein the interface further comprises connectors for cooling.

3. The receptable according to claim 1, wherein the receptable comprises a mechanical interface adapted for locking a module for computation in place.

4. The receptable according to claim 1, wherein the receptable comprises a guide for guiding a module for computation in place during installation.

5. A module interface for a module for computation, wherein the module interface comprises connectors for power and networking, wherein the connectors are adapted for connection to a corresponding receptacle according to claim 1 having a mating interface,
wherein the module for computation is a standard freight container.

6. The module interface according to claim 5, wherein the module interface further comprises connectors for cooling.

7. The module interface according to claim 5, wherein the module interface further comprises a member for engaging with a receptacle comprising a mechanical interface adapted for locking a module for computation in place.

8. The module interface according to claim 5, wherein the module interface further comprises a module guide to interface with a receptacle comprising a guide for guiding a module for computation in place during installation.

9. A module for computation comprising a module interface according to claim 5, for engaging with a receptable,
wherein the receptable comprises a mating interface for connection to the module interface,
wherein the module for computation is a standard freight container.

10. A method for installing a module for computation according to claim 9, comprising a module interface provided with a module guide, into the receptable, the method comprises steps of:
1) lowering the module until the module guide (420) interfaces with a guide (320) for guiding the module for computation in place
2) lowering the module further into the receptacle until the module interface connectors for power and networking connects to the corresponding connectors for power and networking of the receptacle.

11. The method according to claim 10, further comprising a step of locking the module for computation in place, wherein the receptacle comprises a mechanical interface, and the module is locked through the mechanical interface.
